(19) United States
(12) Patent Application Publication
(10) Pub. No.: US 2025/0144764 A1
(43) Pub. Date: May 8, 2025

(54) POLISHING PAD WITH IMPROVED SLURRY FLOWABILITY AND PROCESS FOR PREPARING A SEMICONDUCTOR DEVICE USING THE SAME

(71) Applicant: SK enpulse Co., Ltd., Gyeonggi-do (KR)

(72) Inventors: Yujin SHIN, Gyeonggi-do (KR); Jongwook YOON, Gyeonggi-do (KR); Joonho AN, Gyeonggi-do (KR); Kyunghwan KIM, Gyeonggi-do (KR); Jangwon SEO, Gyeonggi-do (KR)

(21) Appl. No.: 18/817,224

(22) Filed: Aug. 28, 2024

(30) Foreign Application Priority Data
Nov. 6, 2023 (KR) 10-2023-0152067

(51) Int. Cl. B24B 37/22; B24B 37/04; H01L 21/306

(52) U.S. Cl. CPC B24B 37/22; B24B 37/042; H01L 21/30625

(57) ABSTRACT

As specially designed second grooves in a radial form are adopted in addition to first grooves in a concentric form in the polishing pad according to an embodiment, slurry flowability can be improved, and wafer profile and polishing rate can be changed. Accordingly, the polishing pad according to the embodiment can be used in the fabrication of semiconductor devices to enhance process efficiency and product quality.

### CROSS-REFERENCE TO RELATED PATENT APPLICATION

This application claims priority under 35 U.S.C. §119 to Korean Patent Application No. 10-2023-0152067, filed on Nov. 6, 2023, the disclosure of which is incorporated herein by reference in its entirety.

### TECHNICAL FIELD

Embodiments relate to a polishing pad for use in a chemical mechanical planarization (CMP) process of semiconductor devices. Specifically, they relate to a polishing pad with improved slurry flowability and to a process for preparing a semiconductor device using the same.

### BACKGROUND ART

The chemical mechanical planarization (CMP) in a process for preparing semiconductors refers to a step in which a semiconductor substrate such as a wafer is fixed to a head and in contact with the surface of a polishing pad mounted on a platen, and the surface of the semiconductor substrate is then chemically treated by supplying a slurry while the platen and the head are relatively moved, to thereby mechanically planarize the irregularities on the surface of the semiconductor substrate.

A polishing pad is an essential member that plays an important role in such a CMP process. In general, a polishing pad is composed of a polyurethane resin and has grooves on its surface for a large flow of a slurry and pores for supporting a fine flow thereof.

For the preparation of such a polishing pad, a diisocyanate and a polyol are reacted to obtain a prepolymer, which is mixed with a curing agent and a foaming agent and then cured to obtain a polyurethane foam sheet. Thereafter, the upper and lower surfaces of the polyurethane foam sheet are sliced to the desired thickness to obtain a top-pad, grooves are formed in a specific shape using a tip or the like on the surface of the top-pad, and it is then bonded with a polyurethane lower pad to prepare a polishing pad.

The grooves may be of various shapes. For example, the groove may have a shape of circles that share a center (see Korean Laid-open Patent Publication No. 2005-0095818). The grooves provided on a polishing pad serve to assist the planarization of the surface of a wafer by carrying a slurry while allowing the slurry to flow.

### PRIOR ART DOCUMENT

(Patent Document 1) Korean Laid-open Patent Publication No. 2005-0095818

### DISCLOSURE OF INVENTION

### Technical Problem

A polishing pad in a CMP process removes the film substance while polishing the wafer surface. The slurry flowability varies depending on the type of slurry and film substance, resulting in changes in the polishing rate and within-wafer non-uniformity (WIWNU) value. A method of adjusting the process conditions is used to modify the wafer profile, which consumes time and materials.

As a result of research conducted by the present inventors, it has been discovered that, as specially designed radial grooves are adopted in addition to concentric grooves, slurry flowability can be improved, and wafer profile and polishing rate can be changed.

Accordingly, an object of the embodiments is to provide a polishing pad with improved slurry flowability and polishing rate, and a process for preparing a semiconductor device using the same.

### Solution to Problem

According to an embodiment to accomplish the above object, there is provided a polishing pad, which comprises a polishing layer having a polishing surface, wherein the polishing layer comprises a plurality of first grooves having a circular shape and sharing the center of the polishing surface; and a plurality of second grooves formed radially from a position distanced from the center by 10% to 90% of the radius of the polishing surface to the outer periphery, and when the silicon oxide layer of a silicon wafer is polished using a ceria slurry on the polishing surface, and when the polishing rate is measured at 30 or more random locations, the within-wafer non-uniformity (WIWNU) calculated by the following equation is 15% or less.

$$W I W N U ( \% ) = \frac{RR\_stdev}{RR\_avg} \times 100$$

Here, RR_stdev is the standard deviation of the polishing rate (Å/minute) measurements, and RR_avg is the average of the polishing rate (Å/minute) measurements.

According to still another embodiment, there is provided a process for preparing a semiconductor device, which comprises polishing the surface of a semiconductor substrate using the polishing pad.

### Advantageous Effects of Invention

As specially designed second grooves in a radial form are adopted in addition to first grooves in a concentric form in the polishing pad according to the embodiment, slurry flowability can be improved, and wafer profile and polishing rate can be changed.

In particular, the adoption of the second grooves can improve CMP slurry flowability to change the polishing rate and wafer profile in the central region of a wafer, thereby reducing the WIWNU value and increasing the lifespan of the pad.

Accordingly, the polishing pad according to the embodiment can be used in the fabrication of semiconductor devices to enhance process efficiency and product quality.

### BRIEF DESCRIPTION OF DRAWINGS

FIG. 1 is the plan view of a polishing pad according to an embodiment.

FIG. 2 illustrates a process for preparing a semiconductor device using a polishing pad according to an embodiment.

FIG. 3 is a cross-sectional view of a polishing layer comprising first grooves taken along the line A1-A1′ in FIG. 1.

FIG. 4 is a cross-sectional view of a polishing layer comprising second grooves taken along the line A2-A2′ in FIG. 1.

FIG. 5 shows the wafer profile after the CMP process using the polishing pads obtained in Examples 1 to 3 and Comparative Examples 1 and 2.

### REFERENCE NUMERAL OF THE DRAWINGS

100: polishing layer, 101: polishing surface,

200: support layer, 300: adhesive layer,

110: first groove, 120: second groove, 130: third groove,

111, 121: inner side, 112, 122: bottom side,

h1: depth of the first groove, h2: depth of the second groove,

w1: width of the first groove, w2: width of the second groove,

t: thickness of the polishing layer, p: pitch interval of the first grooves,

A1-A1′, A2-A2′: cutting lines,

400: polishing pad, 500: platen, 600: conditioner, 700: polishing slurry,

810: polishing head, 820: carrier, 900: semiconductor substrate (wafer)

### BEST MODE FOR CARRYING OUT THE INVENTION

In the following description of the embodiments, a detailed description of known functions and configurations incorporated herein will be omitted when it is determined that the description may make the subject matter of the embodiments rather unclear. In addition, for the sake of description, the sizes of individual elements in the appended drawings may be exaggeratedly depicted or omitted, and they may differ from the actual sizes.

In the present specification, when one component is described to be formed on/under another component or connected or coupled to each other, it covers the cases where these components are directly or indirectly formed, connected, or coupled through another component. In addition, it should be understood that the criterion for the terms on and under of each component may vary depending on the direction in which the object is observed.

In this specification, terms referring to the respective components are used to distinguish them from each other and are not intended to limit the scope of the embodiment. In addition, in the present specification, a singular expression is interpreted to cover a plural number as well unless otherwise specified in the context.

Throughout the present specification, the terms first, second, and the like are used to describe various components. But the components should not be limited by the terms. The terms are used for the purpose of distinguishing one element from another.

In the present specification, the term “comprising” is intended to specify a characteristic, region, step, process, element, and component. It does not exclude the presence or addition of any other characteristic, region, step, process, element, and component, unless specifically stated to the contrary.

For convenience, the molecular weight of compounds or polymers described in the present specification is expressed in units of molar mass, but it may be understood as relative mass with reference to carbon-12. In addition, the molecular weight of compounds or polymers described in the present specification may be interpreted as a number average molecular weight or a weight average molecular weight, for example, as a number average molecular weight.

In the numerical range that limits the size, physical properties, and the like of components described in the present specification, when a numerical range limited with the upper limit only and a numerical range limited with the lower limit only are separately exemplified, it should be understood that a numerical range combining these upper and lower limits is also encompassed in the exemplary scope of the invention.

### Polishing Pad

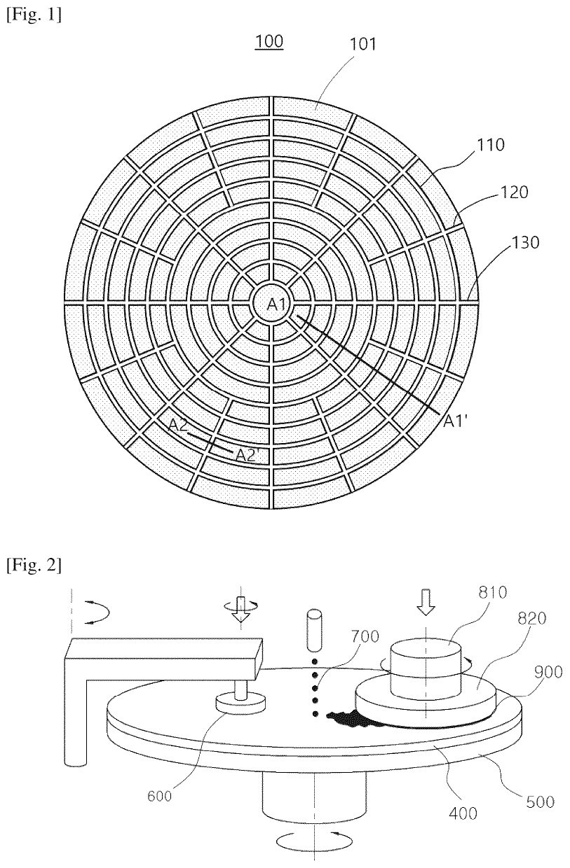

FIG. 1 is the plan view of a polishing pad according to an embodiment. Referring to FIG. 1, the polishing pad according to an embodiment comprises a polishing layer (100) having a polishing surface (101).

For example, the polishing layer may comprise a urethane-based polymer and may be porous. The urethane-based polymer may be formed by a curing reaction of a urethane-based prepolymer and a curing agent. Specifically, the polishing layer may be formed from a polishing layer composition that comprises a urethane-based prepolymer, a curing agent, a foaming agent, and other additives.

The polishing layer may comprise pores. The pores may have a structure of a closed cell. The average diameter of the pores may be 5 μm to 200 μm. In addition, the polishing layer may comprise 20% by volume to 70% by volume of pores relative to the total volume of the polishing layer. That is, the porosity of the polishing layer may be 20% by volume to 70% by volume.

The thickness of the polishing layer is not particularly limited. Specifically, the average thickness of the polishing layer may be 0.8 mm to 5.0 mm, 1.0 mm to 4.0 mm, 1.0 mm to 3.0 mm, 1.5 mm to 2.5 mm, 1.7 mm to 2.3 mm, or 2.0 mm to 2.1 mm.

The polishing layer (100) comprises a plurality of first grooves (110) having a circular shape and sharing the center of the polishing surface (101); and a plurality of second grooves (120) formed radially from a position distanced from the center by 10% to 90% of the radius of the polishing surface to the outer periphery.

The first grooves serve to enhance the polishing efficiency by lowering the flowability of a slurry. The second grooves serve to increase the flowability of a slurry, thereby discharging debris generated during the polishing process.

As described above, the first grooves and the second grooves serve to control the flowability of a slurry during a CMP process. The combination thereof can appropriately control the degree of maintenance and renewal of a slurry, thereby enhancing the polishing efficiency.

In particular, the second grooves do not extend from the center of the polishing surface;

rather, they extend from a position distanced away from the center. As a result, in a CMP process, the slurry flowability changes in the area of the polishing surface in contact with a semiconductor substrate such as a wafer, thereby adjusting the wafer profile.

The position from which the second grooves extend may be distanced from the center of the polishing surface by, for example, 10% or more, 20% or more, 30% or more, 40% or more, 50% or more, 60% or more, 70% or more, or 80% or more, of the radius of the polishing surface. As a specific example, the position from which the second grooves extend may be distanced from the center of the polishing surface by 10% to 39%, 40% to 59%, or 60% to 90%, of the radius of the polishing surface.

In a specific embodiment, the second grooves may comprise at least one of (i) to (iii) below.

(i) a plurality of second-A grooves formed radially from a position distanced from the center by 10% to 39% of the radius of the polishing surface to the outer periphery,

(ii) a plurality of second-B grooves formed radially from a position distanced from the center by 40% to 59% of the radius of the polishing surface to the outer periphery, and

(iii) a plurality of second-C grooves formed radially from a position distanced from the center by 60% to 90% of the radius of the polishing surface to the outer periphery.

In addition, referring to FIG. 1, the polishing pad may further comprise a plurality of third grooves (130) formed radially from the center of the polishing surface (101) to the outer periphery.

When the third grooves are adopted as a radial groove in addition to the second grooves, the effect of increasing the flowability of a slurry to discharge debris generated during the polishing process can be further enhanced.

FIG. 2 illustrates a process for preparing a semiconductor device using a polishing pad according to an embodiment.

Referring to FIG. 2, once the polishing pad (400) according to an embodiment has been attached to a platen (500), a semiconductor substrate (900) as an object to be polished is disposed on the polishing layer of the polishing pad (400). In such an event, the surface of the semiconductor substrate (900) to be polished is in direct contact with the polishing surface of the polishing pad (400). A polishing slurry (700) may be sprayed through a nozzle onto the polishing pad for polishing. Thereafter, the semiconductor substrate (900) and the polishing pad (400) rotate relatively to each other, so that the surface of the semiconductor substrate (900) is polished. In such an event, the rotation direction of the semiconductor substrate (900) and the rotation direction of the polishing pad (400) may be the same direction or opposite directions. The semiconductor substrate (900) mounted on the polishing head (810) is pressed against the polishing surface of the polishing pad (400) at a predetermined load to be in contact therewith, and the surface thereof may then be polished.

As the specially designed grooves in a radial form are adopted in addition to the grooves in a concentric form in the polishing pad according to an embodiment, slurry flowability can be improved in a CMP process, and wafer profile and polishing rate can be changed. In particular, the adoption of the second grooves can improve CMP slurry flowability to change the polishing rate and wafer profile in the central region of a wafer, thereby reducing the WIWNU value and increasing the lifespan of the pad.

Within-wafer non-uniformity (WIWNU) is a value related to polishing flatness and uniformity during a CMP process using a polishing pad. Once a CMP process of semiconductor devices such as wafers has been carried out using a polishing pad, the polishing rate is measured at multiple points. Then, it is calculated using the following equation.

$$W I W N U ( \% ) = \frac{RR\_stdev}{RR\_avg} \times 100$$

Here, RR_stdev is the standard deviation of the polishing rate (Å/minute) measurements, and RR_avg is the average of the polishing rate (Å/minute) measurements.

The standard deviation (RR_stdev) of the polishing rate can be calculated using the following equation.

$$RR\_stdev = \sqrt{\frac{\sum {( R R - RR\_avg )}^{2}}{n}}$$

Here, RR is the polishing rate measurement at each point, RR_avg is the average of the polishing rate measurements, and n is the number of the polishing rate measurements.

A polishing pad with a WIWNU at a certain level or less may produce high-quality semiconductor devices with excellent polishing flatness and uniformity in a CMP process.

According to an embodiment, when the silicon oxide layer of a silicon wafer is polished using a ceria slurry on the polishing surface, and when the polishing rate is measured at 30 or more random locations, the within-wafer non-uniformity (WIWNU) calculated by the above equation is 15% or less.

For example, the WIWNU of the polishing pad may be 15% or less, 14% or less, 13% or less, 12% or less, 11% or less, 10% or less, 9% or less, 8% or less, or 7% or less. Meanwhile, the lower limit of the WIWNU is not particularly limited, but it may be, for example, 0% or more, 1% or more, 2% or more, 3% or more, 4% or more, or 5% or more. Specifically, the WIWNU of the polishing pad may be 0% to 15%, more specifically, 1% to 8%.

In addition, the polishing rate (removal rate) may be calculated using the following equation by measuring the film thickness of a semiconductor device such as a wafer before and after a CMP process.

Polishing rate (Å/minute)=difference in thickness before and after polishing (Å)/polishing time (minute)

The standard deviation (RR_stdev) of the polishing rate may be, for example, 1,000Å/minute or less, 700 Å/minute or less, 500 Å/minute or less, or 400 Å/minute or less. Specifically, the difference between the maximum and minimum of the standard deviation (RR_stdev) of the polishing rates may be 0 Å/minute to 1,000 Å/minute, 10 Å/minute to 700 Å/minute, 50 Å/minute to 500 Å/minute, or 100 Å/minute to 400 Å/minute.

In addition, the difference between the maximum and minimum of the polishing rate measurements may be, for example, 2,000 Å/minute or less, 1,500 Å/minute or less, 1,000 Å/minute or less, or 500 Å/minute or less. Specifically, the difference between the maximum and minimum of the polishing rate measurements may be 0 Å/minute to 2,000 Å/minute, 10 Å/minute to 1,500 Å/minute, 50 Å/minute to 1,000 Å/minute, or 100 Å/minute to 500 Å/minute.

Additionally, the average polishing rate (RR_avg) may be, for example, 2,000 Å/minute to 4,000 Å/minute, 2,500 Å/minute to 4,000 Å/minute, 3,000 Å/minute to 3,500 Å/minute, or 2,000 Å/minute to 3,400 Å/minute.

In a specific embodiment, the WIWNU may be 1% to 8%, and the RR_avg may be 2,500 Å/minute to 4,000 Å/minute. In another specific embodiment, the RR_avg may be 3,200 Å/minute to 3,400 Å/minute. It may be more advantageous for obtaining a desired level of effect in a CMP process within the above preferred range of polishing rate.

### Groove

Referring to FIG. 1, the polishing layer (100) of the polishing pad comprises a plurality of first grooves (110) having a circular shape and sharing the center of the polishing surface; and a plurality of second grooves (120) formed radially from a position distanced from the center by 10% to 90% of the radius of the polishing surface to the outer periphery. In addition, the polishing pad may further comprise a plurality of third grooves (130) formed radially from the center of the polishing surface (101) to the outer periphery.

The number of the first grooves formed in the polishing layer may be 10 or more, 30 or more, 50 or more, 70 or more, or 90 or more, and may be 200 or less, 190 or less, 170 or less, and 150 or less, 130 or less, or 120 or less, specifically, 10 to 200, 50 to 170, 70 to 150, or 90 to 130.

In addition, the number of the second grooves formed in the polishing layer may be 2 or more, 4 or more, 6 or more, 8 or more, 10 or more, or 12 or more, and 100 or less, 50 or less, 40 or less, 30 or less, or 20 or less, specifically, 2 to 100, 2 to 50, 4 to 50, or 4 to 40.

In a specific embodiment, the polishing layer may comprise the first grooves in a total of 50 to 150 and the second grooves in a total of 2 to 50.

In another specific embodiment, the polishing layer may comprise the first grooves in a total of 50 to 150, the second grooves in a total of 4 to 50, and the third grooves in a total of 4 to 50.

In addition, the planar shape of the second grooves may be, for example, a plurality of straight lines formed radially at a constant angular spacing and extending from a position distanced from the center to the outer periphery.

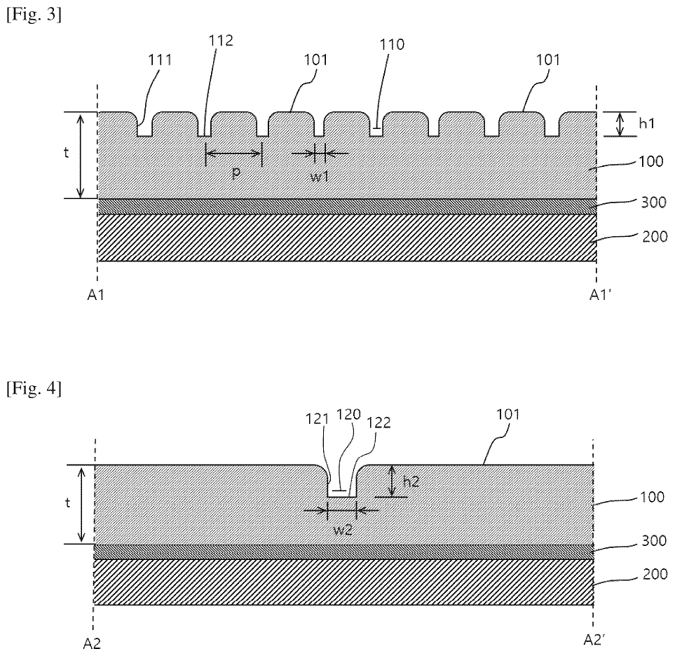

Referring to FIGS. 3 and 4, the first grooves and the second grooves may comprise inner surfaces (111 and 121) perpendicular to the polishing surface and bottom surfaces (112 and 122) parallel to the polishing surface.

Referring to FIG. 3, the width (w1) of the first groove (110) is a value obtained by measuring the width of the bottom surface (112) of the first groove. The depth (h1) of the first groove (110) is a value obtained by measuring the vertical straight distance between the bottom surface (112) and the polishing surface (101).

The width (w1) of the first groove (110) may be, for example, 0.1 mm or more, 0.2 mm or more, or 0.3 mm or more, and may be 1 mm or less, 0.9 mm or less, or 0.8 mm or less, as a specific example, 0.1 mm to 1 mm.

The depth (h1) of the first groove (110) may be, for example, 0.4 mm or more, 0.5 mm or more, or 0.6 mm or more, and may be 1.2 mm or less, 1.1 mm or less, or 1.0 mm or less, as a specific example, 0.4 mm to 1.2 mm.

Referring to FIG. 3, the width (w2) of the second groove (120) is a value obtained by measuring the width of the bottom surface (122) of the second groove. The depth (h2) of the second groove (120) is a value obtained by measuring the vertical straight distance between the bottom surface (122) and the polishing surface (101).

The width (w2) of the second groove (120) may be, for example, 0.5 mm or more, 0.6mm or more, or 0.7 mm or more, and may be 1.5 mm or less, 1.4 mm or less, or 1.3 mm or less, as a specific example, 0.5 mm to 1.5 mm.

The depth (h2) of the second groove (120) may be, for example, 0.5 mm or more, 0.6 mm or more, or 0.7 mm or more, and may be 1.5 mm or less, 1.4 mm or less, or 1.3 mm or less, as a specific example, 0.5 mm to 1.5 mm.

In a specific embodiment, the width of the first grooves may be 0.1 mm to 1 mm, and the width of the second grooves may be 0.5 mm to 1.5 mm.

In another specific embodiment, the depth of the first grooves may be 0.4 mm to 1.2 mm, and the depth of the second grooves may be 0.5 mm to 1.5 mm.

The depth of the second grooves may be equal to, or deeper than, the depth of the first grooves. For example, the depth of the second grooves may be 100% to 300% of the depth of the first grooves. Alternatively, the depth of the second grooves may be greater than 100% to 300% or greater than 100% to 250% of the depth of the first grooves. Alternatively, the depth of the second grooves may be 110% to 300%, for example, 120% to 300%, for example, 120% to 200%, or, for example, 125% to 150% of the depth of the first grooves. Within the above range, it is possible to increase the flowability of a slurry, whereby the discharge of debris generated in the polishing process can be more efficiently performed.

In addition, the depth (h2) of the second grooves may be 90% or less of the thickness (t) of the polishing layer. Specifically, the depth of the second grooves may be 70% or less, or 50% or less, of the thickness of the polishing layer. More specifically, the depth of the second grooves may be 10% to 60%, 20% to 50%, or 30% to 50% of the thickness of the polishing layer. Within the above range, it is possible to prevent the deformation of the polishing layer due to the formation of the grooves while the flowability of a slurry can be further enhanced.

The width of the second grooves may be 50% to 200% of the width of the first grooves.

Specifically, the width of the second grooves may be 100% to 200% of the width of the first grooves. Alternatively, the width of the second grooves may be 100% to 180%, for example, 100% to 170%, for example, 100% to 165%, or, for example, 100% to 160% of the width of the first grooves. Within the above range, it is advantageous for enhancing the flowability of a slurry while securing a sufficient polishing area.

In addition, the width of the third grooves is a value obtained by measuring the width of the bottom surface of the third grooves. The depth of the third grooves is a value obtained by measuring the vertical straight distance between the bottom surface of the third grooves and the

The width of the third grooves may be, for example, 0.5 mm or more, 0.6 mm or more, or 0.7 mm or more, and may be 1.5 mm or less, 1.4 mm or less, or 1.3 mm or less, as a specific example, 0.5 mm to 1.5 mm.

The depth of the third grooves may be, for example, 0.5 mm or more, 0.6 mm or more, or 0.7 mm or more, and may be 1.5 mm or less, 1.4 mm or less, or 1.3 mm or less, as a specific example, 0.5 mm to 1.5 mm.

The first grooves may be adopted in plural numbers and spaced apart from each other at certain distance intervals. The second grooves may be adopted in plural numbers and spaced apart from each other at certain angular intervals. In addition, the third grooves may be adopted in plural numbers and spaced apart from each other at certain angular intervals. The polishing layer may comprise a plurality of the first grooves at a constant pitch spacing. Referring to FIG. 3, the pitch spacing (p) of the first grooves (110) refers to the straight distance between the midpoints of the bottom surfaces (112) of any two of the first grooves. Specifically, the polishing layer may have the first grooves at a pitch spacing of 1 mm to 10 mm. Alternatively, the polishing layer may have the first grooves at a pitch spacing of 1 mm to 5 mm. Alternatively, the polishing layer may have the first grooves at a pitch spacing of 2 mm to 4 mm.

In addition, the polishing layer may have the second grooves at a certain angle, for example, at a spacing of 10° to 50°, 15° to 45°, or 20° to 40°. In addition, the polishing layer may have the third grooves at a certain angle, for example, at a spacing of 10° to 50°, 15° to 45°, or 20° to 40°.

### Additional Constituent Elements

Referring to FIGS. 3 and 4, the polishing pad may further comprise a support layer (200) disposed under the lower side of the polishing layer (100).

The support layer serves to support the polishing layer and to absorb and disperse an impact applied to the polishing layer. The hardness of the support layer may be smaller than the hardness of the polishing layer. The support layer may comprise a nonwoven fabric or a porous pad.

The support layer may comprise pores. The pores contained in the support layer may have a structure of an opened cell. The pores contained in the support layer may have a shape that extends in the thickness direction of the support layer. In addition, the porosity of the support layer may be greater than the porosity of the polishing layer.

In addition, the polishing pad may further comprise an adhesive layer (300) interposed between the polishing layer (100) and the support layer (200). The adhesive layer serves to bond the polishing layer and the support layer to each other. Further, the adhesive layer may suppress a polishing liquid from leaking from the upper part of the polishing layer downward to the support layer.

The adhesive layer may comprise a hot melt adhesive. Specifically, the adhesive layer may comprise a hot-melt adhesive having a melting point of 90° C. to 130° C. More specifically, the adhesive layer may comprise a hot-melt adhesive having a melting point of 110° C. to 130° C.

The hot melt adhesive may be at least one selected from the group consisting of a polyurethane resin, a polyester resin, an ethylene-vinyl acetate resin, a polyamide resin, and a polyolefin resin. Specifically, the hot melt adhesive may be at least one selected from the group consisting of a polyurethane resin and a polyester resin.

The thickness of the adhesive layer may be 5 μm to 30 μm, specifically 20 to 30 μm, more specifically 23 μm to 27 μm.

In addition, the polishing pad may further comprise a window in the polishing layer. The window helps to determine the termination point of a CMP process by in-situ measuring the flatness and thickness of the surface of a wafer.

For example, the polishing layer has a first penetrating hole in the thickness direction, and a window may be inserted into the first penetrating hole. In addition, the support layer has a second penetrating hole in the thickness direction, and the first penetrating hole and the second penetrating hole may be connected to each other.

The window may be formed from a window composition that comprises a urethane-based prepolymer and a curing agent. Preferably, the window may be a non-foam. It is possible that no microbubbles are present in the window.

For example, the window may have a thickness of 2.3 mm to 2.5 mm, a light transmittance of 60% to 80%, and a refractive index of 1.45 to 1.60.

### Process for Preparing a Polishing Pad

The process for preparing a polishing pad according to an embodiment comprises (1) preparing a polishing layer comprising a polishing surface; (2) forming a plurality of first grooves having a circular shape and sharing the center of the polishing surface; and (3) forming a plurality of second grooves formed radially from a position distanced from the center by 10% to 90% of the radius of the polishing surface to the outer periphery. Steps (2) and (3) may be carried out sequentially or simultaneously.

In addition, the process for preparing a polishing pad may further comprise, in addition to steps (1) to (3), (4) forming a plurality of third grooves formed radially from the center of the polishing surface to the outer periphery. Steps (2) to (4) may be carried out sequentially or simultaneously. Alternatively, step (2) may be carried out first, and steps (3) and (4) may be carried out simultaneously.

Hereinafter, each step will be described in detail.

In step (1), a polishing layer comprising a polishing surface is prepared.

The polishing layer may comprise a urethane-based polymer prepared from a composition that comprises a urethane-based prepolymer, a curing agent, a foaming agent, and other additives.

A prepolymer generally refers to a polymer having a relatively low molecular weight wherein the degree of polymerization is adjusted to an intermediate level so as to conveniently mold a molded article to be finally produced.

A prepolymer may be molded by itself or after a reaction with another polymerizable compound. Specifically, the urethane-based prepolymer may be prepared by reacting an isocyanate compound with a polyol and may comprise an unreacted isocyanate group (NCO). The isocyanate compound and the polyol compound are not particularly limited as long as they can be used for preparing a urethane-based polymer.

The curing agent may be at least one of an amine compound and an alcohol compound. Specifically, the curing agent may comprise at least one compound selected from the group consisting of an aromatic amine, an aliphatic amine, an aromatic alcohol, and an aliphatic alcohol.

The foaming agent is not particularly limited as long as it is commonly used for forming voids in a polishing pad. For example, the foaming agent may be at least one selected from a solid phase foaming agent having a hollow structure, a liquid phase foaming agent using a volatile liquid, and an inert gas.

In the above step (2), a plurality of first grooves having a circular shape and sharing the center of the polishing surface are formed. In addition, in step (3), a plurality of second grooves formed radially from a position distanced from the center by 10% to 90% of the radius of the polishing surface to the outer periphery are formed.

In such an event, the depth of the second grooves and that of the third grooves may be equal to, or deeper than, the depth of the first grooves. To this end, the second grooves and the third grooves may be formed later than the first grooves. If the second grooves are formed first, it may be inconvenient and difficult to form them deeper than the first grooves.

In addition, the specific configurations of the depths, widths, spacings, and the like of the first grooves, the second grooves, and the third grooves are as exemplified above with respect to the polishing pad.

The formation of the first grooves, the second grooves, and the third grooves may be carried out by cutting and removing a portion of the polishing surface. For example, the cutting may be carried out using a tip. The polishing surface of the polishing layer may be cut by a tip to form a groove. Specifically, the tip is fixed so as to abut the polishing surface of the polishing layer, and then the polishing pad, which comprises the polishing layer, may be rotated or moved in a desired direction to remove a portion of the surface of the polishing layer, thereby forming a groove. The formation of the first grooves, the second grooves, and the third grooves may comprise forming an inner surface perpendicular to the polishing surface and a bottom surface parallel to the polishing surface by the cutting.

In addition, the process for preparing a polishing pad may further comprise, after the formation of the grooves, machining the edge at which the polishing surface meets the inner surface into a curved surface.

The curvature machining may be carried out by removing a portion of the edge at which the polishing surface meets the inner surface of the groove. The curvature machining may be carried out by using a grinder or a chock. Specifically, the curvature machining may be carried out by removing a portion of the edge at which the polishing surface meets the inner surface of the groove such that the radius of curvature becomes 0.1 mm to 5 mm, 0.1 mm to 2 mm, or 0.3 mm to 1.5 mm. If the radius of curvature is within the above range, such defects as scratches on the surface of a wafer can be effectively prevented during a CMP process.

The curvature machining may be carried out by using a grinder. In addition, the grinder may comprise a grinding surface. That is, the edge at which the polishing surface meets the inner surface of the groove may be machined into a curved surface by the grinding surface of the grinder.

In addition, the grinder can machine the edge at which the inner surface of the groove meets the polishing surface into a curved surface while it rotates. In such an event, the rotating speed of the grinder may be 1,000 rpm to 50,000 rpm, 2,000 rpm to 35,000 rpm, or 5,000 rpm to 20,000 rpm.

The groove forming step and the curvature machining step as described above may be continuously carried out. As an example, the tip for forming the grooves and the grinder or the chock for the curvature machining are disposed adjacent to each other, so that the groove formation and the curvature machining can be continuously carried out on the polishing surface.

### Process for Preparing a Semiconductor Device

A semiconductor device may be fabricated through chemical and mechanical polishing using the polishing pad described above.

The process for preparing a semiconductor device according to an embodiment comprises polishing the surface of a semiconductor substrate using the polishing pad according to an embodiment. Specifically, the process for preparing a semiconductor device may comprise providing the polishing pad according to an embodiment; and relatively rotating the polishing surface of the polishing layer and the surface of a semiconductor substrate while they are in contact with each other to polish the surface of the semiconductor substrate.

FIG. 2 illustrates a process for preparing a semiconductor device using a polishing pad according to an embodiment.

First, once the polishing pad (400) according to an embodiment has been attached to a platen (500), a semiconductor substrate (900) as an object to be polished is disposed on the polishing pad (400). In such an event, the surface of the semiconductor substrate (900) to be polished is in direct contact with the polishing surface of the polishing pad (400). A polishing slurry (700) may be sprayed through a nozzle onto the polishing pad for polishing. The flow rate of the polishing slurry (700) supplied through the nozzle may be selected according to the purpose within a range of about 10 cm³/minute to about 1,000 cm³/minute. For example, it may be about 50 cm³/minute to about 500 cm³/minute, but it is not limited thereto.

Thereafter, the semiconductor substrate (900) and the polishing pad (400) rotate relatively to each other, so that the surface of the semiconductor substrate (900) is polished. In such an event, the rotation direction of the semiconductor substrate (900) and the rotation direction of the polishing pad (400) may be the same direction or opposite directions. The rotation speeds of the semiconductor substrate (900) and the polishing pad (400) may each be selected according to the purpose within a range of about 10 rpm to about 500 rpm. For example, it may be about 30 rpm to about 200 rpm, but it is not limited thereto.

The semiconductor substrate (900) mounted on the polishing head (810) is pressed against the polishing surface of the polishing pad (400) at a predetermined load to be in contact therewith, and the surface thereof may then be polished. The load applied to the polishing surface of the polishing pad (400) and the surface of the semiconductor substrate (900) by the polishing head (810) may be selected according to the purpose within a range of about 1 gf/cm² to about 1,000 gf/cm². For example, it may be about 10 gf/cm² to about 800 gf/cm², but it is not limited thereto.

In an embodiment, the semiconductor substrate (900) as an object to be polished may comprise an oxide layer, a tungsten layer, or a composite layer thereof. Specifically, the semiconductor substrate (900) may comprise an oxide layer, a tungsten layer, or a composite layer of an oxide layer and a tungsten layer. The composite layer of an oxide layer and a tungsten layer may be a multilayer film in which the tungsten layer is laminated on one side of the oxide layer or may be a single-layer film in which an oxide region and a tungsten region are mixed in a single layer. As the object to be polished has such a film substance, and, at the same time, the polishing pad has characteristics according to the embodiment, a semiconductor device fabricated according to the process for preparing a semiconductor device may have minimum defects.

In an embodiment, the process for preparing a semiconductor device may further comprise, in the step of polishing the object to be polished, supplying any one of a slurry for polishing an oxide layer and a slurry for polishing a tungsten layer; or sequentially supplying the slurry for polishing an oxide layer and the slurry for polishing a tungsten layer to the polishing surface.

For example, if the semiconductor substrate as an object to be polished comprises an oxide layer, the process for preparing a semiconductor device may comprise supplying a slurry for polishing an oxide layer. If the semiconductor substrate comprises a tungsten layer, the process for preparing a semiconductor device may comprise supplying a slurry for polishing a tungsten layer. If the semiconductor substrate comprises a composite layer of an oxide layer and a tungsten layer, the process for preparing a semiconductor device may comprise sequentially supplying a slurry for polishing an oxide layer and a slurry for polishing a tungsten layer to the polishing surface. Here, depending on the process, the slurry for polishing an oxide layer may be supplied first and then the slurry for polishing a tungsten layer may be supplied later, or the slurry for polishing a tungsten layer may be supplied first and then the slurry for polishing an oxide layer may be supplied later.

In an embodiment, in order to maintain the polishing surface of the polishing pad (400) in a state suitable for polishing, the process for preparing a semiconductor device may further comprise processing the polishing surface of the polishing pad (400) with a conditioner (600) simultaneously with polishing the semiconductor substrate (900).

### MODE FOR THE INVENTION

Although the following examples are provided, the scope of possible implementations is not limited thereto.

### Example 1: Preparation of a Polishing Pad

### Step 1: Preparation of a Polishing Layer

A casting machine equipped with tanks and feeding lines for a prepolymer, a curing agent, an inert gas, and a reaction rate controlling agent was provided. A urethane-based prepolymer with NCO end groups (NCO content: 8.0%, brand name: PUGL-450D, SKC) was charged to the prepolymer tank, bis(4-amino-3-chlorophenyl)methane (Ishihara) was charged to the curing agent tank, an argon (Ar) gas was charged to the inert gas tank, and a tertiary amine-based reaction rate promoting agent (brand name: A1, Air Product) was charged to the reaction rate controlling agent tank. The prepolymer, the curing agent, the inert gas, and the reaction rate controlling agent were stirred while they were fed to the mixing head at constant rates through the respective feeding lines. In such an event, the prepolymer and the curing agent were fed while their equivalent ratio in the reactor was adjusted, wherein the total feeding amount was maintained at a rate of 10 kg/minute. In addition, the reaction rate controlling agent was fed in a constant amount of 0.5% by weight based on the total feeding rate of the prepolymer and the curing agent. In addition, the inert gas was fed in a constant volume of 20% based on the total volume of the prepolymer and the curing agent. The mixed raw materials were injected into a mold (1,000 mm×1,000 mm×3 mm) and reacted to obtain a molded article in the form of a solid cake. Thereafter, the top and bottom of the molded article were each ground by a thickness of 0.5 mm to obtain a polishing layer having a thickness of 2 mm.

### Step 2: Formation of First Grooves (Concentric Grooves)

Concentric first grooves were formed on the polished surface of the polishing layer using a tip. Specifically, the tip is fixed so as to abut the polishing surface of the polishing layer, and then the polishing pad, which comprises the polishing layer, was rotated to remove a portion of the surface of the polishing layer, thereby forming first grooves. The first grooves (concentric grooves) were formed in a total of 117 (with a pitch interval of 3.047 mm) sharing the center of the polishing surface. Each of the first grooves was formed to have a width of 0.47 mm and a depth of 0.846 mm.

### Step 3: Formation of Second Grooves and Third Grooves (Radial Grooves)

Second grooves and third grooves in a radial form were formed on the polishing surface of the polishing layer using a tip. Specifically, the tip is fixed so as to abut the polishing surface of the polishing layer, and then the polishing pad, which comprises the polishing layer, was moved to remove a portion of the surface of the polishing layer, thereby forming second grooves and third grooves. The second grooves were formed radially extending from the 30^{th} of the first grooves when counted from the center of the polishing surface to the outer periphery of the polishing surface. The third grooves were formed radially extending from the center of the polishing surface to the outer periphery of the polishing surface. The second grooves in a total of 16 were formed at an angular interval of about 22.5°. The third grooves (extending from the center) in a total of 16 were formed at an angular interval of about 22.5°. The second grooves and the third grooves were formed alternately with each other, so that the angular interval between the second grooves and the third grooves was about 11.25°. In addition, each of the second grooves was formed to have a width of 0.96 mm and a depth of 1.012 mm. Each of the third grooves was formed to have a width of 0.96 mm and a depth of 1.012 mm.

As a result, a polishing pad was obtained with the first grooves (concentric grooves), the second grooves (radial grooves extending from the 30^{th} concentric groove when counted from the center), and the third grooves (radial groove extending from the center) formed on its polishing surface.

### Examples 2 and 3: Preparation of a Polishing Pad

The same procedure as in Example 1 was repeated to prepare a polishing pad, except that the position from which the second grooves extended was changed as shown in Table 1 below and that the individual groove dimensions were adjusted as shown in Table 2 below.

### Comparative Example 1: Preparation of a Polishing Pad

The same procedure as in Example 1 was repeated to prepare a polishing pad, except that only the first grooves were formed as shown in Tables 1 and 2 below, without forming the second groove and the third groove.

### Comparative Example 2: Preparation of a Polishing Pad

The same procedure as in Example 1 was repeated to prepare a polishing pad, except that only the first grooves and the third grooves were formed as shown in Tables 1 and 2 below, without forming the second groove.

TABLE 1

| | C. Ex. 1 | C. Ex. 2 | Ex. 1 | Ex. 2 | Ex. 3 |
|---|---|---|---|---|---|
| No. of the first grooves | 117 | 117 | 117 | 117 | 117 |
| No. of the third grooves | — | 32 | 16 | 16 | 16 |
| Position from which the | — | — | 30 | 59 | 88 |
| second grooves extended | | | | | |
| (The number of the first | | | | | |
| groove) | | | | | |
| No. of the second | — | — | 16 | 16 | 16 |
| grooves | | | | | |

TABLE 2

| | | C. Ex. 1 | C. Ex. 2 | Ex. 1 | Ex. 2 | Ex. 3 |
|---|---|---|---|---|---|---|
| First | Width (mm) | 0.476 | 0.476 | 0.470 | 0.476 | 0.475 |
| grooves | Depth (mm) | 0.880 | 0.880 | 0.846 | 0.840 | 0.855 |
| | Pitch (mm) | 3.047 | 3.047 | 3.046 | 3.046 | 3.046 |
| Second | Width (mm) | — | — | 0.960 | 0.960 | 0.962 |
| grooves | Depth (mm) | — | — | 1.012 | 1.005 | 1.02 |
| | Angle (°) | — | — | 22.5 | 22.5 | 22.5 |
| Third | Width (mm) | — | 0.959 | 0.96 | 0.96 | 0.962 |
| grooves | Depth (mm) | — | 1.028 | 1.012 | 1.005 | 1.02 |
| | Angle (°) | — | 22.5 | 22.5 | 22.5 | 22.5 |

### Test Example 1: Evaluation of CMP

The polishing pads prepared in the Examples and Comparative Examples were each used for evaluating CMP as follows.

### (1) Polishing Rate (Removal Rate)

A silicon wafer having a diameter of 300 mm on which silicon oxide had been deposited by a CVD process was set on the porous polyurethane polishing pad mounted on the platen in a CMP polishing machine, while the silicon oxide layer of the silicon wafer faced downward. Then, the silicon oxide layer was polished under a polishing load of 4.0 psi while the polishing pad was rotated at a speed of 150 rpm, a calcined ceria slurry was supplied onto the polishing pad at a rate of 250 ml/minute, and the platen was rotated at a speed of 150 rpm for 60 seconds. Upon completion of the polishing, the silicon wafer was detached from the carrier, mounted in a spin dryer, washed with deionized water (DIW), and then dried with nitrogen for 15 seconds. The film thickness of the dried silicon wafer was measured before and after the polishing using a spectral reflectometer-type thickness measuring instrument (manufacturer: Keyence, model: SI-F80R). The polishing rate was calculated using the following Equation.

Polishing rate (Å/minute)=difference in thickness before and after polishing (Å)/polishing time (minute)

### (2) WIWNU

Polishing was performed for 1 minute under the same polishing conditions as in Section (1) above. The polishing rate of the silicon wafer thus polished was measured at 47 locations. The within-wafer non-uniformity (WIWNU) was calculated according to the following equation. The locations of the individual points where the polishing rate was measured were randomly selected.

$$W I W N U ( \% ) = \frac{RR\_stdev}{RR\_avg} \times 100$$

Here, RR_stdev is the standard deviation of the polishing rate (Å/minute) measurements, and RR_avg is the average of the polishing rate (Å/minute) measurements.

The standard deviation (RR_stdev) of the polishing rate can be calculated using the following equation.

$$RR\_stdev = \sqrt{\frac{\sum {( R R - RR\_avg )}^{2}}{n}}$$

Here, RR is the polishing rate measurement at each point, RR_avg is the average of the polishing rate measurements, and n is the number of the polishing rate measurements.

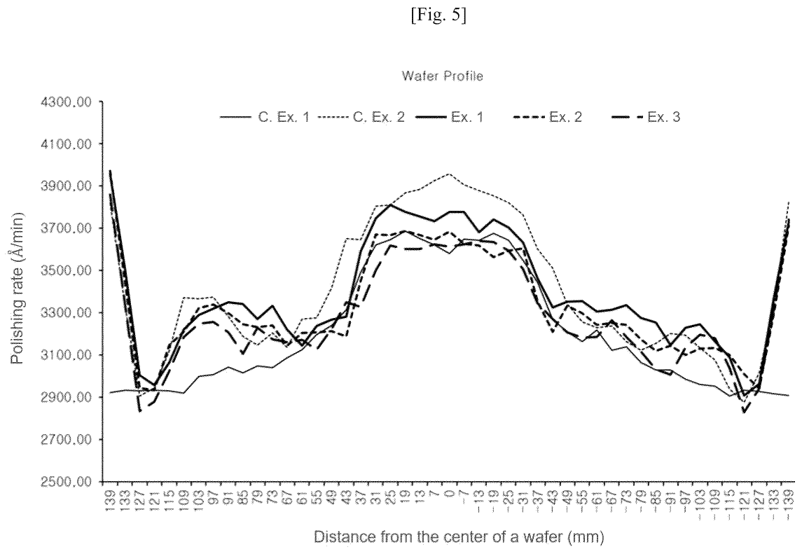

The test results are shown in the table below. In addition, the wafer profile after CMP using each polishing pad is shown in FIG. 5.

TABLE 3

| | | C. Ex. 1 | C. Ex. 2 | Ex. 1 | Ex. 2 | Ex. 3 |
|---|---|---|---|---|---|---|
| Polishing | Average | 3,198.1 | 3,406.9 | 3,389.6 | 3,330.5 | 3,285.7 |
| rate | (Å/min) | | | | | |
| | Relative | 100 | 107 | 106 | 104 | 103 |
| | value (%) | | | | | |

| | | | | | |
|---|---|---|---|---|---|
| WIWNU (%) | 9 | 9 | 8 | 7 | 7 |

As a result of the test, the wafer profile in Examples 1 to 3 changed due to the adoption of the second grooves. In particular, the WIWNU value was reduced through the profile change in the central area of the wafer. This indicates that CMP process performance can be enhanced by adopting the second grooves and changing the position from which they extend.

1. A polishing pad, which comprises a polishing layer having a polishing surface, wherein the polishing layer comprises a plurality of first grooves having a circular shape and sharing the center of the polishing surface; and a plurality of second grooves formed radially from a position distanced from the center by 10% to 90% of the radius of the polishing surface to the outer periphery, and
when the silicon oxide layer of a silicon wafer is polished using a ceria slurry on the polishing surface, and when the polishing rate is measured at 30 or more random locations, the within-wafer non-uniformity (WIWNU) calculated by the following equation is 15% or less:
$$W I W N U ( \% ) = \frac{RR\_stdev}{RR\_avg} \times 100$$
wherein RR_stdev is the standard deviation of the polishing rate (Å/minute) measurements, and RR_avg is the average of the polishing rate (Å/minute) measurements.

2. The polishing pad of claim 1, wherein the WIWNU is 1% to 8%, and the RR_avg is 2,500 Å/minute to 4,000 Å/minute.

3. The polishing pad of claim 2, wherein the RR_avg is 3,200 Å/minute to 3,400 Å/minute.

4. The polishing pad of claim 1, wherein the polishing layer comprises the first grooves in a total of 50 to 150 and the second grooves in a total of 2 to 50.

5. The polishing pad of claim 4, wherein the width of the first groove is 0.1 mm to 1 mm, and the width of the second groove is 0.5 mm to 1.5 mm.

6. The polishing pad of claim 5, wherein the depth of the first groove is 0.4 mm to 1.2 mm, and the depth of the second groove is 0.5 mm to 1.5 mm.

7. The polishing pad of claim 1, wherein the second grooves comprise at least one of (i) to (iii) below:
(i) a plurality of second-A grooves formed radially from a position distanced from the center by 10% to 39% of the radius of the polishing surface to the outer periphery,
(ii) a plurality of second-B grooves formed radially from a position distanced from the center by 40% to 59% of the radius of the polishing surface to the outer periphery, and
(iii) a plurality of second-C grooves formed radially from a position distanced from the center by 60% to 90% of the radius of the polishing surface to the outer periphery.

8. The polishing pad of claim 1, which further comprises a plurality of third grooves formed radially from the center of the polishing surface to the outer periphery.

9. The polishing pad of claim 8, wherein the polishing layer comprises the first grooves in a total of 50 to 150, the second grooves in a total of 4 to 50, and the third grooves in a total of 4 5 to 50.

10. A process for preparing a semiconductor device, which comprises polishing the surface of a semiconductor substrate using the polishing pad of claim 1.
